(19) United States
(12) Patent Application Publication
(10) Pub. No.: US 2025/0318390 A1
(43) Pub. Date: Oct. 9, 2025

(54) DISPLAY PANEL AND DISPLAY DEVICE

(71) Applicant: HKC CORPORATION LIMITED, Shenzhen (CN)

(72) Inventors: HONGSONG WANG, Shenzhen (CN); Haijiang YUAN, Shenzhen (CN)

(21) Appl. No.: 19/089,017

(22) Filed: Mar. 25, 2025

(30) Foreign Application Priority Data
Apr. 8, 2024 (CN) 202410414030.0

(51) Int. Cl. H10K 59/35; H10K 59/131; H10K 59/80

(52) U.S. Cl. CPC H10K 59/35; H10K 59/131; H10K 59/873

(57) ABSTRACT

A display panel includes a substrate and multiple pixel modules used to emit light independently. The substrate is divided into multiple installation regions. A first groove is defined in each installation region. Each pixel module is installed in the respective first groove. A first magnet is disposed at a bottom of the pixel module. A second magnet is disposed on each of two opposite sides of the pixel module. A third magnet is disposed at a position of the first groove corresponding to the first magnet. A fourth magnet is disposed at a groove wall of the first groove corresponding to the second magnet. A magnetic force between the first and the third magnet is greater than a magnetic force between the second and the fourth magnet. The first and the third magnet have opposite magnetic polarities. The second and the fourth magnet have opposite magnetic polarities.

### CROSS-REFERENCE TO RELATED APPLICATIONS

This application claims the priority and benefit of Chinese patent application number 2024104140300, titled “Display Panel and Display Device” and filed Apr. 8, 2024 with China National Intellectual Property Administration, the entire contents of which are incorporated herein by reference.

### TECHNICAL FIELD

This application relates to the display field, and more particularly to a display panel and a display device.

### BACKGROUND

With the rapid development of display devices, OLED (Organic Light-Emitting Diode) display panels are becoming more and more popular because of their superior colors and image display effects. An OLED display panel can rely on each pixel module to emit light independently, so that one or more pixel modules can form display effects of different formats.

In the process of assembling a display panel, pixel modules need to be installed one by one on the substrate. Due to the large number of pixel modules, installation errors are prone to occur, and it is difficult to ensure that each pixel module is installed at the specified position. In addition, such installation is time-consuming and labor-intensive, which greatly reduces the assembly efficiency of the display panel.

Therefore, how to quickly install multiple pixel modules at designated positions on a substrate and improve the assembly efficiency of a display panel has become an urgent problem to be solved in the art.

### SUMMARY

Embodiments of the present application disclose a display panel and a display device, one purpose of which is to quickly install a plurality of pixel modules at designated positions of a substrate, thereby improving the assembly efficiency of the display panel.

Embodiments of the present application disclose a display panel. The display panel includes a substrate and a plurality of pixel modules. The plurality of pixel modules are used for emitting light independently. The substrate is divided into a plurality of installation regions. A first groove is disposed in each installation region. The respective pixel module is installed in the first groove. A first magnet is disposed at a bottom of the pixel module. A second magnet is disposed on each of opposite sides of the pixel module. A third magnet is disposed at a position of the first groove corresponding to the first magnet. A fourth magnet is disposed at the position on a groove wall of the first groove corresponding to the second magnet. A magnetic force between the first magnet and the third magnet is greater than a magnetic force between the second magnet and the fourth magnet. The first magnet and the third magnet have opposite magnetic polarities. The second magnet and the fourth magnet have opposite magnetic polarities.

In some embodiments, the substrate includes a first airflow channel. The first airflow channel is disposed at a bottom of the first groove and is communicated to the bottom of the first groove. A second airflow channel and a third airflow channel are disposed on the two opposite side walls of the first groove. The second airflow channel and the third airflow channel are respectively communicated to the sides of the side walls of the first groove adjacent to the pixel module. A control assembly is disposed in the substrate. The control assembly is connected to each of the first airflow channel, the second airflow channel, and the third airflow channel separately. The display panel further includes an air pump, which is disposed on a side of the substrate facing away from the pixel module. A main air flow channel is further disposed on the substrate. The main air flow channel is connected between the air pump and the control assembly. When the air pump is turned on, the control assembly controls the second airflow channel, the first airflow channel, and the third airflow channel to be communicated to the main air flow channel in turn for a preset time within equal time intervals.

In some embodiments, there are multiple fourth magnets, and the multiple fourth magnets are arranged at intervals along the side wall of the first groove in a direction perpendicular to the substrate. The second airflow channel and the third airflow channel each include a main airway and multiple airway branches. The main airway extends from the side wall of the first groove in a direction perpendicular to the substrate and is connected to the control assembly. Each airway branch is located in the gap between two adjacent fourth magnets, and one end is connected to the side of the side wall of the first groove adjacent to the pixel module, and the other end is connected to the side of the main airway adjacent to the pixel module.

In some embodiments, the first magnet is disposed in a middle of the pixel module. A second groove is disposed at a position of the first groove corresponding to the first magnet. A shape of the second groove matches a shape of the first magnet, and the first magnet is embedded in the second groove. The first airflow channel includes a first main airway, a second main airway, a plurality of first airway branches, and a plurality of second airway branches. One end of the first main airway is connected to the control assembly, and the other end extends along a length direction of the substrate. One end of the second main airway is connected to the control assembly, and the other end extends along the length direction of the substrate. The first main airway and the second main airway are arranged at intervals. The plurality of first airway branches are arranged at intervals, and one end is communicated to the bottom of the first groove, and the other end is communicated to the side of the first main airway adjacent to the first groove. The plurality of second airway branches are arranged at intervals, and one end is communicated to the bottom of the first groove, and the other end is communicated to the side of the second main airway adjacent to the first groove. The first airway branches and the second airway branches are respectively disposed on both sides of the second groove. When the air pump is turned on, the control assembly controls the first main airway and the second main airway to be communicated to the main air flow channel in turn for a preset time within equal time intervals.

In some embodiments, the substrate includes a circuit control layer. The control assembly includes a circuit board. The circuit board is electrically connected to the circuit control layer. The circuit control layer provides an electrical signal to the circuit board. The circuit board includes a signal processing module, a control module, and a plurality of solenoid valves. The signal processing module is electrically connected to the control module. The control module is electrically connected to the plurality of solenoid valves. The signal processing module is used to receive a detection signal. The solenoid valve includes a first solenoid valve, a second solenoid valve, a third solenoid valve, and a fourth solenoid valve. One end of the first solenoid valve, one end of the second solenoid valve, one end of the third solenoid valve, and one end of the fourth solenoid valve are each connected to the main air flow channel. The other end of the first solenoid valve is connected to the main airway of the second airflow channel, and the first solenoid valve controls the main airway of the second airflow channel to be connected to or cut off from the main air flow channel. The other end of the second solenoid valve is connected to the first main airway, and the second solenoid valve controls the first main airway to be connected to or cut off from the main air flow channel. The other end of the third solenoid valve is connected to the second main airway, and the third solenoid valve controls the second main airway to be connected to or cut off from the main air flow channel. The other end of the fourth solenoid valve is connected to the main airway of the third airflow channel, and the fourth solenoid valve controls the main airway of the third airflow channel to be connected to or cut off from the main air flow channel. When the signal processing module receives the detection signal, the signal processing module transmits the detection signal to the control module. The control module controls the first solenoid valve, the second solenoid valve, the third solenoid valve, and the fourth solenoid valve to be opened for a preset time within equal time intervals.

In some embodiments, the display panel further includes a plurality of cameras. At least two of the cameras are disposed at diagonals of the substrate. The cameras are electrically connected to the circuit control layer. The cameras are used to detect a display state of the pixel module. When the camera detects that the pixel module is in the first display state, the camera transmits a detection signal to the signal processing module.

In some embodiments, the display panel further includes a lifting device and a first cover plate. The first cover plate is made of a transparent material. Ab orthographic projection area of the first cover plate on the substrate is greater than or equal to an orthographic projection area of the plurality of installation regions on the substrate. There are at least two lifting devices, and the at least two lifting devices are respectively connected to both sides of the substrate. The top of each lifting device is connected to the first cover plate. The lifting devices can drive the first cover plate to rise and fall in a direction perpendicular to the substrate. When the pixel modules are installed, the lifting devices drive the first cover plate to cover the plurality of pixel modules and abut against the plurality of pixel modules to be lying in the same plane.

In some embodiments, the display panel further includes a second cover plate. An orthographic projection area of the second cover plate on the substrate is equal to an orthographic projection area of the first cover plate on the substrate. The second cover plate includes a through hole corresponding to each installation region, and the area of the through hole is larger than the area of the pixel module. The second cover plate is disposed between the first cover plate and the lifting devices, and is detachably connected to the first cover plate and the lifting devices. Before the pixel modules are installed, the lifting devices drive the second cover plate to rise to a preset height.

In some embodiments, each pixel module includes a pixel driving circuit, and the pixel driving circuit drives the pixel module to emit light and display. The pixel driving circuit includes a communication unit and a control unit. The communication unit is used to receive a data signal. The communication unit transmits the data signal to the control unit. The control unit controls the pixel module to emit light and display. The pixel module includes a base, and a light-emitting layer and an encapsulation layer that are sequentially arranged on the base. A power receiving terminal is arranged on the side of the base facing away from the light-emitting layer. A power supply terminal is arranged in the substrate corresponding to the power receiving terminal. The power supply terminal provides an electrical signal to the power receiving terminal to power up the pixel driving circuit.

Embodiments of the present application further disclose a display device, including a housing. The display device further includes the above-mentioned display panel, and the display panel is arranged in the housing.

In the present application, a first groove is defined in the substrate, and a second magnet and a fourth magnet are disposed in the first groove. A first magnet and a third magnet are disposed at corresponding positions on the pixel module. When installing multiple pixel modules, the multiple pixel modules can be poured on the substrate first. Since the first magnet of the pixel module and the corresponding third magnet on the substrate have a relatively large magnetic force, after the pixel module contacts the substrate, the pixel module may first be attracted toward the direction of the third magnet through the first magnet, so that the pixel module approaches the first groove. When approaching the first groove, the third magnets on both sides of the pixel module may generate magnetic attraction with the fourth magnets on the groove wall of the first groove. Even if the position of the pixel module does not correspond to the position of the first groove at the beginning, the third magnet and the fourth magnet will attract each other to make the pixel module rotate to the position matching the first groove and embed the pixel module into the first groove. That is, the present application uses the first magnet and the third magnet with a relatively stronger magnetic force to attract each other, thus fixing the pixel module to the substrate by magnetic attraction, so that the pixel module is not easy to fall off from the substrate. The second magnet and the fourth magnet with a relatively weaker magnetic force are used to adjust the alignment between the pixel module and the first groove, so that the pixel module can be quickly and accurately installed in the first groove. In this way, multiple pixel modules 170 can be quickly installed at the specified positions of the substrate, thereby improving the assembly efficiency of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative efforts.

FIG. 1 is a schematic diagram of a first embodiment of a display panel of the present application.

FIG. 2 is a schematic diagram of a pixel module in the first embodiment of the display panel of the present application.

FIG. 3 is a top view of the pixel module in the first embodiment of the display panel of the present application.

FIG. 4 is a top view of a substrate in the first embodiment of the display panel of the present application.

FIG. 5 is a schematic diagram of a second embodiment of the display panel of the present application.

FIG. 6 is a partial schematic diagram of a left side of a substrate in the second embodiment of the display panel of the present application.

FIG. 7 is a schematic diagram of a third embodiment of the display panel of the present application.

FIG. 8 is a schematic diagram of a fourth embodiment of the display panel of the present application.

FIG. 9 is a schematic diagram of a second cover plate in the fourth embodiment of the display panel of the present application.

FIG. 10 is a schematic diagram of an embodiment of a display device of the present application.

In the drawings: 10, display device; 100, display panel; 200, housing; 110, substrate; 111, installation region; 112, first groove; 113, third magnet; 114, fourth magnet; 115, second groove; 116, first airflow channel; 117, first main airway; 118, first airway branch; 119, second main airway; 120, second airway branch; 121, second airflow channel; 122, main airway; 123, airway branch; 124, third airflow channel; 130, control assembly; 131, circuit board; 132, signal processing module; 133, control module; 134, solenoid valve; 135, first solenoid valve; 136, second solenoid valve; 137, third solenoid valve; 138, fourth solenoid valve; 140, air pump; 150, main air flow channel; 160, circuit control layer; 161, power supply terminal; 170, pixel module; 171, first magnet; 172, second magnet; 173, pixel driving circuit; 174, communication unit; 175, control unit; 176, base; 177, power receiving terminal; 178, light-emitting layer; 179, encapsulation layer; 180, camera; 190, lifting device; 191, first cover plate; 192, second cover plate; 193, through hole.

### DETAILED DESCRIPTION OF EMBODIMENTS

The present application is described in detail below with reference to the accompanying drawings and optional embodiments. It should be noted that, under the premise of no conflict, the embodiments or technical features described below can be arbitrarily combined to form new embodiments.

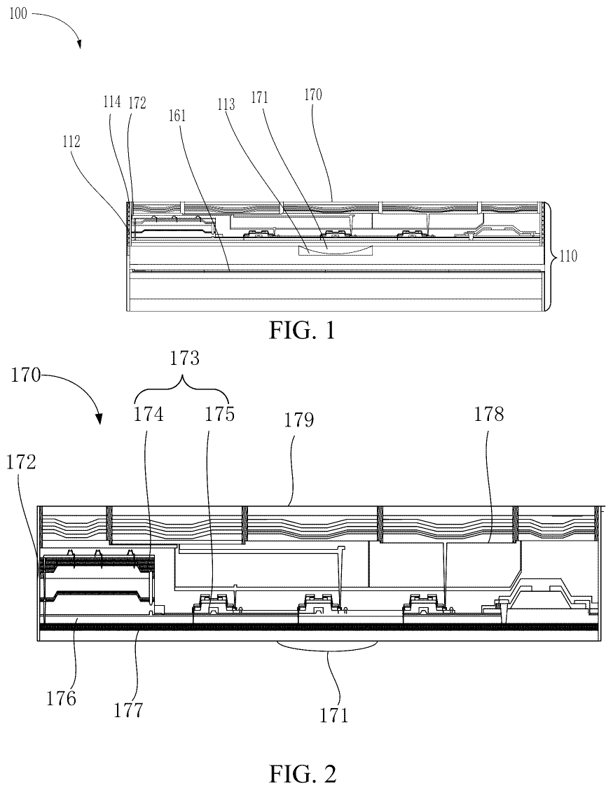

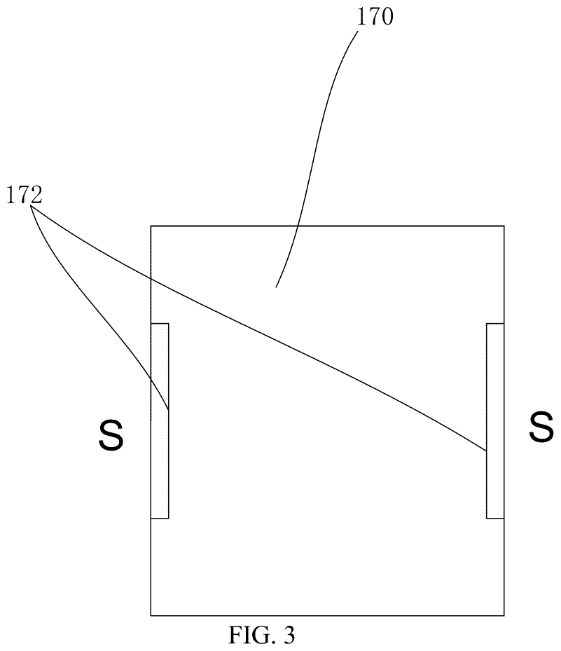

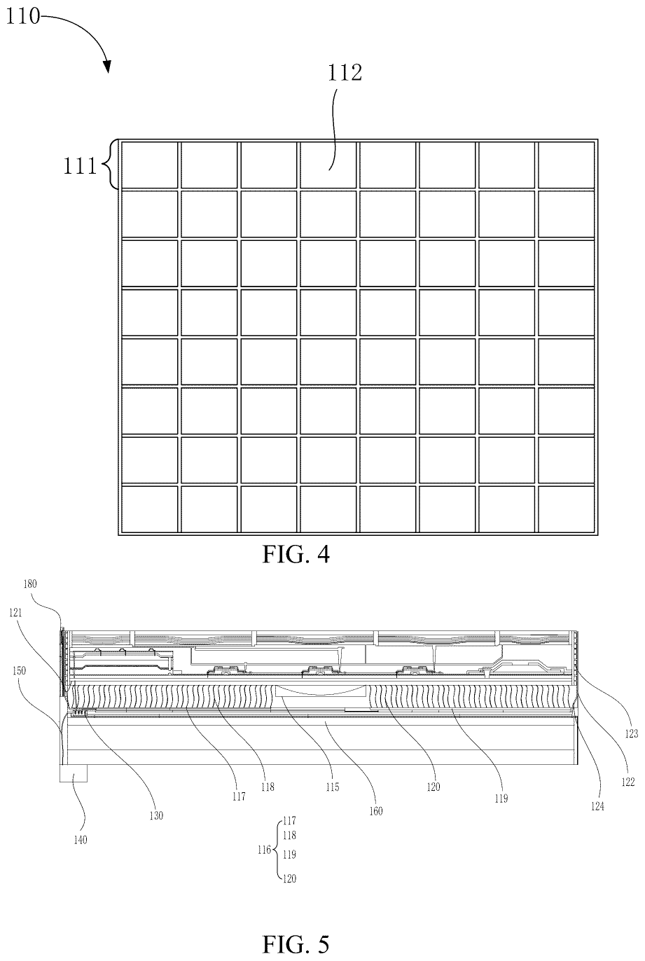

FIG. 1 is a schematic diagram of a first embodiment of a display panel of the present application. FIG. 2 is a schematic diagram of a pixel module in the first embodiment of the display panel of the present application. FIG. 3 is a top view of the pixel module in the first embodiment of the display panel of the present application. FIG. 4 is a top view of a substrate in the first embodiment of the display panel of the present application. As shown in FIG. S. 1 to 4, embodiments of the present application disclose a display panel 100. The display panel 100 includes a substrate 110 and a plurality of pixel modules 170. The pixel modules 170 are used for emitting light independently. The substrate 110 is divided into a plurality of installation regions 111. A first groove 112 is disposed in each installation region 111, and the respective pixel module 170 is installed in the first groove 112. A first magnet 171 is disposed at a bottom of the pixel module 170. A second magnet 172 is disposed on each of two opposite sides of the pixel module 170. A third magnet 113 is arranged at a position of the first groove 112 corresponding to the first magnet 171. A fourth magnet 114 is arranged at a position of a groove wall of the first groove 112 corresponding to each second magnet 172. A magnetic force between the first magnet 171 and the third magnet 113 is greater than a magnetic force between the second magnet 172 and the fourth magnet 114. The first magnet 171 and the third magnet 113 have opposite magnetic polarities. The second magnet 172 and the fourth magnet 114 have opposite magnetic polarities.

In the present application, a first groove 112 is defined in the substrate 110, and a second magnet 172 and a fourth magnet 114 are disposed in the first groove 112. A first magnet 171 and a third magnet 113 are disposed at corresponding positions on the pixel module 170. When installing multiple pixel modules 170, the multiple pixel modules 170 can be poured on the substrate 110 first. Since the first magnet 171 of the pixel module 170 and the corresponding third magnet 113 on the substrate 110 have a relatively large magnetic force, after the pixel module 170 contacts the substrate 110, the pixel module 170 may first be attracted toward the direction of the third magnet 113 through the first magnet 171, so that the pixel module 170 approaches the first groove 112. When approaching the first groove 112, the third magnets 113 on both sides of the pixel module 170 may generate magnetic attraction with the fourth magnets 114 on the groove wall of the first groove 112. Even if the position of the pixel module 170 does not correspond to the position of the first groove 112 at the beginning, the third magnet 113 and the fourth magnet 114 will attract each other to make the pixel module 170 rotate to the position matching the first groove 112 and embed the pixel module 170 into the first groove 112. That is, the present application uses the first magnet 171 and the third magnet 113 with a relatively stronger magnetic force to attract each other, thus fixing the pixel module 170 to the substrate 110 by magnetic attraction, so that the pixel module 170 is not easy to fall off from the substrate 110. The second magnet 172 and the fourth magnet 114 with a relatively weaker magnetic force are used to adjust the alignment between the pixel module 170 and the first groove 112, so that the pixel module 170 can be quickly and accurately installed in the first groove 112. In this way, multiple pixel modules 170 can be quickly installed at the specified positions of the substrate 110, thereby improving the assembly efficiency of the display panel 100.

It should be noted that in the display panel 100 of the present application, each pixel module 170 can be displayed individually as one pixel of the display panel 100. Multiple sub-pixels in each pixel module 170 constitute a pixel. The multiple sub-pixels include a red light-emitting unit R, a green light-emitting unit G, and a blue light-emitting unit B. That is, each pixel module 170 includes only one pixel unit. A pixel unit includes a red sub-pixel, a green sub-pixel, and a blue sub-pixel. Three sub-pixels of different colors can be used to display any color by adjusting to different grayscale voltages. This is equivalent to each pixel unit on the display panel 100 forming a module, and the display panel 100 realizes display through each modular pixel module 170.

Specifically, each pixel module 170 includes a pixel driving circuit 173, and the pixel driving circuit 173 drives the pixel module 170 to emit light for display. The pixel driving circuit 173 includes a communication unit 174 and a control unit 175. The communication unit 174 is used to receive a data signal. The communication unit 174 transmits the data signal to the control unit 175. The control unit 175 controls the pixel module 170 to emit light for display. The pixel module 170 includes a base 176, and a light-emitting layer 178 and an encapsulation layer 179 that are sequentially arranged on the base 176. A power receiving terminal 177 is arranged on the side of the base 176 facing away from the light-emitting layer 178. A power supply terminal 161 is arranged in the substrate 110 corresponding to the power receiving terminal 177. The power supply terminal 161 provides an electrical signal to the power receiving terminal 177 to power up the pixel driving circuit 173.

For example, when the signal transmission mode of the pixel module 170 is a wireless transmission mode, the power receiving terminal 177 includes a first coil, the power supply terminal 161 includes a second coil, and multiple power supply terminals 161 are disposed in one-to-one correspondence with the power receiving terminals 177 on multiple pixel modules 170. The first coil and the second coil transmit signals wirelessly to realize the power supply to the pixel module 170.

Specifically, the communication unit 174 includes a wireless receiving module, which is used to receive an external data signal and generate a data control signal according to the external signal and transmit the data control signal to the control unit 175. In this embodiment, the signal transmission mode of the pixel module 170 may be a wireless transmission mode. For example, a wireless transmission module and a wireless receiving module may be set externally to cooperate with each other. Take the wifi module as an example, at least multiple wifi receiving modules and one wifi transmission module are included. At least one wifi receiving module is disposed on each pixel module 170. Each pixel module 170 adopts the WiFi module networking mode, and receives the above-mentioned external data signal through the wireless receiving module, thereby realizing the signal transmission of the pixel module 170 and controlling the pixel module 170 to emit light. Of course, in addition to the one-to-multiple method, wireless transmission may also be performed by setting multiple WiFi transmission modules to transmit data in a one-to-one manner.

Of course, the signal transmission of pixel module 170 may also adopt a contact signal transmission method. For example, bare metal gaskets may be respectively disposed at the bottom of pixel module 170 and in the corresponding installation region 111. When pixel module 170 is installed in installation region 111, the corresponding power receiving terminal 177 contacts the power supply terminal to achieve electrical connection. The above data signals and other control signals may also adopt the above transmission method. This application does not specifically limit the signal transmission method of the pixel module 170, and this embodiment only uses wireless transmission as an example for illustration purposes only.

In the present application, the first magnet 171 on the pixel module 170 is magnetically attracted to the corresponding third magnet 113 on the substrate 110 to form a relatively strong magnetic fixation between the pixel module 170 and the substrate 110, and the third magnet 113 on each of both sides of the pixel module 170 is magnetically attracted to the fourth magnet 114 on the side wall of the first groove 112 to form a relatively weak magnetic fixation between the pixel module 170 and the substrate 110, so that multiple pixel modules 170 can be installed on the substrate 110 to prevent the pixel modules 170 from falling from the substrate 110.

When installing the multiple pixel modules 170, the present application mainly first uses a pouring method to pour the multiple pixel modules 170 onto substrate 110, and then uses a magnetic suction method to make the multiple pixel modules 170 fall into the first groove 112 for installation. Therefore, in order to ensure that after the pixel module 170 falls into the first groove 112, the light-emitting surface of the pixel module 170 faces the opening of the first groove 112 instead of the bottom of the first groove 112 thereby ensuring the normal display of the display panel 100, the present application further improves the display panel 100, and the specific improvements are as follows.

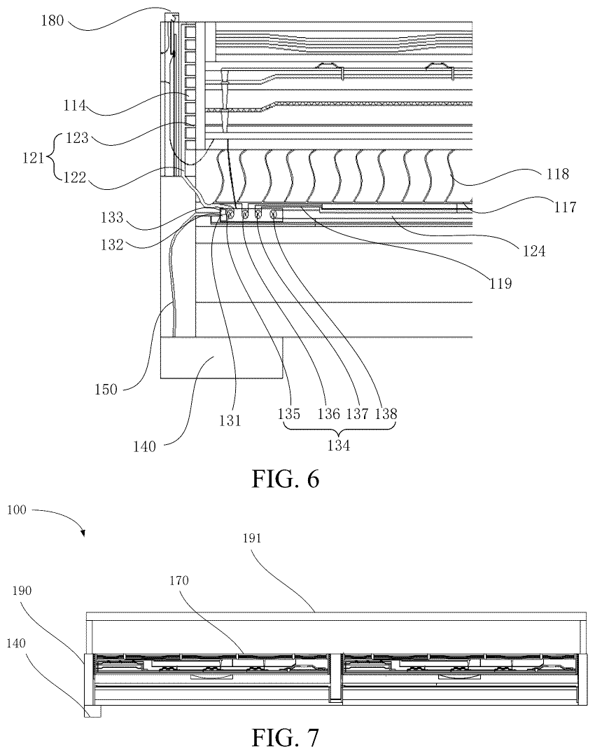

FIG. 5 is a schematic diagram of a second embodiment of the display panel of the present application. FIG. 6 is a partial schematic diagram of a left side of the substrate of the second embodiment of the display panel of the present application. As shown in FIG. 5 and FIG. 6, the embodiment shown in FIG. 5 is an improvement based on FIG. 1. A first airflow channel 116 is disposed in the substrate 110. The first airflow channel 116 is disposed at a bottom of the first groove 112 and is communicated to the bottom of the first groove 112. A second airflow channel 121 and a third airflow channel 124 are respectively defined in two opposite side walls of the first groove 112. The second airflow channel 121 and the third airflow channel 124 are respectively communicated to the side walls of the first groove 112 facing towards the pixel module 170.

A control assembly 130 is disposed in the substrate 110. The control assembly 130 is connected to the first airflow channel 116, the second airflow channel 121, and the third airflow channel 124 separately. The display panel 100 further includes an air pump 140, which is disposed on the side of the substrate 110 facing away from the pixel module 170. A main air flow channel 150 is further disposed on the substrate 110, and the main air flow channel 150 is connected between the air pump 140 and the control assembly 130. When the air pump 140 is turned on, the control assembly 130 controls the second airflow channel 121, the first airflow channel 116, and the third airflow channel 124 to be connected to the main air flow channel 150 in turn for a preset time within equal time intervals.

The difference between this embodiment and the previous embodiment is that the first airflow channel 116, the second airflow channel 121, and the third airflow channel 124 are respectively opened in the substrate 110 and the two opposite side walls of the first groove 112, and the control assembly 130 is used to connect the first airflow channel 116, the second airflow channel 121, and the third airflow channel 124 to the air pump 140 through the main air flow channel 150 in a coded timing manner.

For further convenience of understanding, the specific working principle is explained as follows with an example. When the pixel module 170 partially falls into the first groove 112, the light-emitting surface faces the bottom of the first groove 112. At this time, the first magnet 171 of the pixel module 170 does not form an effective attraction with the third magnet 113 in the first groove 112. In the absence of relatively strong magnetic fixation, the attraction between the weakly magnetic third magnets 113 on both sides of the pixel module 170 for positioning and the fourth magnets 114 on the side walls of the first groove 112 will still make the pixel module 170 loose in the first groove 112.

At this time, the air pump 140 is turned on, so that the gas of the air pump 140 enters the main air flow channel 150. The control assembly 130 first opens the second airflow channel 121, so that the main air flow channel 150 is communicated to the second airflow channel 121. When the second airflow channel 121 is located on the left side wall of the first groove 112, the airflow passes through the second airflow channel 121 and blows toward the left side of the pixel module 170, so that the pixel module 170 rotates from the left side in the first groove 112, and so the second magnet 172 on the pixel module 170 and the fourth magnet 114 on the side wall of the first groove 112 may correspond to each other to form magnetic attraction and positioning during the rotation of the pixel module 170.

After the main air flow channel 150 and the second air flow channel 121 are communicated to each other for 5 seconds, the control assembly 130 controls the main air flow channel 150 and the second air flow channel 121 to be cut off from each other, and controls the first air flow channel 116 and the main air flow channel 150 to be communicated. Since the first air flow channel 116 is located at the bottom of the first groove 112, the air flow will blow towards the bottom of the pixel module 170, so that the pixel module 170 is turned over under the blowing of the air flow, and so the light-emitting surface of the pixel module 170 is turned over from facing the bottom of the first groove 112 to facing the opening of the first groove 112.

After the main air flow channel 150 and the first airflow channel 116 are communicated for 5 seconds, the control assembly 130 controls the main air flow channel 150 and the first airflow channel 116 to be cut off from each other, and the third airflow channel 124 and the main air flow channel 150 are communicated. When the third airflow channel 124 is located on the right side wall of the first groove 112, the airflow passes through the third airflow channel 124 and blows toward the right side of the pixel module 170, so that the pixel module 170 rotates from the right side located in the first groove 112, so that when the left side rotation does not form the alignment between second magnet 172 and the fourth magnet 114, the pixel module 170 can be rotated on the right side so that the pixel module 170 can make the second magnet 172 and the fourth magnet 114 on the side wall of the first groove 112 correspond to each other to form magnetic attraction and positioning during the rotation process.

After the main air flow channel 150 and the third airflow channel 124 are communicated for 5 seconds, the control assembly 130 controls the main air flow channel 150 and the third airflow channel 124 to be cut off from each other. If the position of the pixel module 170 is still not adjusted successfully, continue the above steps, and continue to use the control assembly 130 to control the second airflow channel 121, the first airflow channel 116, and the third airflow channel 124 to be communicated to the main air flow channel 150 in sequence, so that the airflow sweeps the left side, the bottom, and the right side of the pixel module 170 in sequence at the same interval, until the light-emitting surface of the pixel module 170 faces the opening of the first groove 112, and the first magnet 171 and the third magnet 113 are located in corresponding positions and magnetically attracted, and the second magnet 172 and the fourth magnet 114 are located in corresponding positions and magnetically attracted. At this point, the pixel module 170 will be firmly fixed onto the substrate 110, and the airflow will not be able to blow the pixel module 170 into motion, which means that the position of the pixel module 170 has been successfully adjusted.

That is, the present application adjusts the installation position of the pixel module 170 in the first groove 112 by a combination of airflow sweeping and magnetic fixation. When the position of the pixel module 170 needs to be adjusted, the air pump 140 may be turned on so that the gas of the air pump 140 first enters the main air flow channel 150. Then, under the timing control of the control assembly 130, the second airflow channel 121, the first airflow channel 116, and the third airflow channel 124 are sequentially communicated to the main air flow channel 150 for a preset time within equal time intervals, so that the airflow blows the pixel module 170 located in the first groove 112 from the left side, bottom, and right side in turn, thus adjusting the position of the pixel module 170 by rotating and flipping under the blowing of the airflow. In this way, the pixel module 170 is magnetically fixed to the first groove 112 at the correct installation position, and the light-emitting surface of the pixel module 170 faces the opening direction of the first groove 112.

It should be noted that, for the sake of convenience, the present application the communication time of the airflow channel with the control assembly 130 is set to 5 seconds. However, the actual communication time may be set according to specific needs and the above example is not a specific limit on the communication time.

In addition, in order to achieve the adjustment of the installation position of the pixel module 170 in the first groove 112 by a combination of airflow sweeping and magnetic fixation, the present application improves the structure of the airflow channel specifically as follows.

There are multiple fourth magnets 114, and the multiple fourth magnets 114 are arranged at intervals along the side wall of the first groove 112 in a direction perpendicular to the substrate 110. The second airflow channel 121 and the third airflow channel 124 each include a main airway 122 and multiple airway branches 123. The main airway 122 extends from the side wall of the first groove 112 in a direction perpendicular to the substrate 110 and is communicated to the control assembly 130. Each airway branch 123 is disposed in the gap between two adjacent fourth magnets 114, and one end is communicated to the side of the side wall of the first groove 112 adjacent to the pixel module 170, and the other end is communicated to the side of the main airway 122 adjacent to the pixel module 170.

When the control assembly 130 opens the second airflow channel 121 or the third airflow channel 124, the gas may first enter the main airway 122 of the second airflow channel 121 or the third airflow channel 124 from the main airflow channel 150, and then the gas will be diverted from the main airway 122 to multiple airway branches 123, so that the gas will eventually blow out from the airway branch 123 to the left or right side of the pixel module 170, and so the pixel module 170 rotates from the left side in the first groove 112 or from the right side in the first groove 112 under the blowing of the airflow. During the rotation process, the horizontal position of the pixel module 170 is adjusted so that the second magnets 172 on both sides of the pixel module 170 can be magnetically attracted to the fourth magnets 114 of the first groove 112, thereby adjusting the position of the pixel module 170 in the first groove 112 by combining the left or right side airflow blowing and magnetic attraction.

Furthermore, in this embodiment, in order to enable the pixel module 170 to be flipped from multiple directions at the bottom, thereby facilitating the adjustment of the pixel module 170 to the correct position, the present application designs the first airflow channel 116 located at the bottom of the first groove 112, and the specific design is as follows.

The first magnet 171 is disposed in a middle of the pixel module 170. A second groove 115 is disposed at a position of the first groove 112 corresponding to the first magnet 171, and a shape of the second groove 115 matches a shape of the first magnet 171. The first magnet 171 is embedded in the second groove 115. The first airflow channel 116 includes a first main airway 117, a second main airway 119, a plurality of first airway branches 118, and a plurality of second airway branches 120. One end of the first main airway 117 is communicated to the control assembly 130, and the other end extends along a length direction of the substrate 110. One end of the second main airway 119 is communicated to the control assembly 130, and the other end extends along the length direction of the substrate 110. The first main airway 117 and the second main airway 119 are arranged at intervals. The plurality of first airway branches 118 are arranged at intervals, and one end of each first airway branch 118 is communicated to a bottom of the first groove 112, and the other end is communicated to the side of the first main airway 117 adjacent to the first groove 112. The plurality of second airway branches 120 are arranged at intervals, and one end of each second airway branch is communicated to the bottom of the first groove 112, and the other end is connected to the side of the second main airway 119 adjacent to the first groove 112. The first airway branches 118 and the second airway branches 120 are respectively disposed on both sides of the second groove 115. When the air pump 140 is opened, the control assembly 130 controls the first main airway 117 and the second main airway 119 to be communicated to the main air flow channel 150 in turn for a preset time within equal time intervals.

When the pixel module 170 is correctly installed in the first groove 112, the first magnet 171 on the pixel module 170 will be embedded in the second groove 115. The first magnet 171 is limited by the second groove 115, so that the pixel module 170 is not easy to fall off from the first groove 112.

The first airflow channel 116 located at the bottom of the first groove 112 is mainly composed of two parts. The first part is composed of the first main airway 117 and the plurality of first airway branches 118 communicated to the first main airway 117. The second part is composed of the second main airway 119 and the plurality of second airway branches 120 communicated to the second main airway 119. The second groove 115 is actually arranged in the middle of the first groove 112. Therefore, when the plurality of first airway branches 118 and the plurality of second airway branches 120 are respectively located on both sides of the second groove 115, the first main airway 117 is extended to the lower left of the first groove 112, and the plurality of first airway branches 118 are connected to the lower left of the first groove 112, while the second main airway 119 is extended to the lower right of the first groove 112, and the plurality of second airway branches 120 are connected to the lower right of the first groove 112.

When the control assembly 130 communicates the main air flow channel 150 to the first airflow channel 116, the main air flow channel 150 will first be communicated to the first main airway 117. The gas of the air pump 140 enters the first main airway 117 through the main air flow channel 150, and then the first main airway 117 divides the gas to the plurality of first airway branches 118. Since the plurality of first airway branches 118 are located at the lower left of the first groove 112, the airflow will blow out from the lower left of the first groove 112, so that the lower left of the pixel module 170 is lifted by the airflow, and the pixel module 170 is flipped from the left side to the right side, so that the light-emitting surface of the pixel module 170 is flipped from facing the bottom of the first groove 112 to facing the opening of the first groove 112.

After the control assembly 130 communicates the main air flow channel 150 to the first main airway 117 for 5 seconds, the first main airway 117 is closed and the main air flow channel 150 is communicates to the second main airway 119. The gas of the air pump 140 enters the second main airway 119 through the main air flow channel 150. Then the second main airway 119 diverts the gas to the plurality of second airway branches 120. Since the plurality of second airway branches 120 are located at the lower right of the first groove 112, the airflow will blow out from the lower right of the first groove 112, so that the lower right of the pixel module 170 is lifted by the airflow, and the pixel module 170 is flipped from the right side to the left side, so that the light-emitting surface of the pixel module 170 is flipped from facing the bottom of the first groove 112 to facing the opening of the first groove 112.

It should be noted that, in this embodiment, for the sake of ease of understanding, the time for which the main air flow channel 150 is communicated to the first main airway 117 or the second main airway 119 by the control assembly 130 is set to 5 seconds. The actual communication time may be specifically designed depending on the actual situation, and this embodiment does not specifically limit the communication time.

The present application improves the first airflow channel 116, and forms two branches of the first airflow channel 116 to blow the lower left and lower right of the pixel module 170 separately, so that the pixel module 170 can adjust its position by flipping from the left side to the right side, or by flipping from the right side to the left side. In this way, by increasing the flipping directions of the pixel module 170, the success rate of adjusting the pixel module 170 to the specified position is increased. Even if the first flip from left to right is unsuccessful, the position can be adjusted again from the second flip from right to left, thereby increasing the fault tolerance of the position adjustment of the pixel module 170.

Furthermore, in order to realize the communication control of each of the above-mentioned air flow channels to the main air flow channel 150, thereby realizing the position adjustment of the pixel module 170 in the first groove 112 so that the pixel module 170 is installed at a specified position of the first groove 112 thereby ensuring the normal display of the display panel 100, the present application designs a control assembly, which is specifically as follows.

The substrate 110 includes a circuit control layer 160. The control assembly 130 includes a circuit board 131. The circuit board 131 is electrically connected to the circuit control layer 160. The circuit control layer 160 provides an electrical signal to the circuit board 131. A signal processing module 132, a control module 133, and a plurality of solenoid valves 134 are disposed on the circuit board 131. The signal processing module 132 is electrically connected to the control module 133. The control module 133 is electrically connected to the plurality of solenoid valves 134. The signal processing module 132 is used to receive a detection signal. The solenoid valve 134 includes a first solenoid valve 135, a second solenoid valve 136, a third solenoid valve 137, and a fourth solenoid valve 138. One end of first solenoid valve 135, one end of the second solenoid valve 136, one end of third solenoid valve 137, and one end of fourth solenoid valve 138 are each connected to main air flow channel 150. The other end of first solenoid valve 135 is connected to the main airway 122 of the second airflow channel 121. The first solenoid valve 135 controls the communication or cutoff between the main airway 122 of the second airflow channel 121 and the main air flow channel 150. The other end of the second solenoid valve 136 is connected to the first main airway 117. The second solenoid valve 136 controls the communication or cutoff between the first main airway 117 and the main air flow channel 150. The other end of the third solenoid valve 137 is connected to the second main airway 119. The third solenoid valve 137 controls the communication or cutoff between the second main airway 119 and the main air flow channel 150. The other end of the fourth solenoid valve 138 is connected to the main airway 122 of the third airflow channel 124. The fourth solenoid valve 138 controls the communication or cutoff between the main airway 122 of the third airflow channel 124 and the main air flow channel 150. When the signal processing module 132 receives the detection signal, the signal processing module 132 transmits the detection signal to the control module 133. The control module 133 controls the first solenoid valve 135, the second solenoid valve 136, the third solenoid valve 137, and the fourth solenoid valve 138 to open for a preset time within equal time intervals.

The present application mainly controls the opening or closing of each airflow channel by using the coded timing control method to control the opening or closing of the solenoid valves 134 through the control module 133. Specifically, the first solenoid valve 135 controls the opening or closing between the second airflow channel 121 and the main air flow channel 150. The second solenoid valve 136 controls the opening or closing between the first main airway 117 and the main air flow channel 150. The third solenoid valve 137 controls the opening or closing between the second main airway 119 and the main air flow channel 150. The fourth solenoid valve 138 controls the opening or closing between the third airflow channel 124 and the main air flow channel 150.

When the signal processing module 132 receives the detection signal, the signal processing module 132 transmits the detection signal to the control module 133. The control module 133 first controls the first solenoid valve 135 to open, so that the main air flow channel 150 is communicated to the main airway 122 of the second airflow channel 121. The gas of the air pump 140 thus enters the main air flow channel 150, then enters the main airway 122, and is divided into each airway branch 123 through the main airway 122. The air flow blows toward the left side of the pixel module 170, so that the pixel module 170 rotates from the left side located in the first groove 112, so that the pixel module 170 can make the second magnets 172 correspond to the fourth magnets 114 on the side walls of the first groove 112 during the rotation process thus realizing magnetic attraction and positioning.

After the main air flow channel 150 and the second airflow channel 121 are communicated for 5 seconds, the control module 133 controls the first solenoid valve 135 to close and the second solenoid valve 136 to open, so that the main air flow channel 150 and the second airflow channel 121 are cut off, and the first main airway 117 of the first airflow channel 116 is communicated to the main air flow channel 150. The gas of the air pump 140 thus enters the first main airway 117 through the main air flow channel 150. Then the first main airway 117 divides the gas into the plurality of first airway branches 118. The airflow will blow out from the lower left of the first groove 112, so that the lower left of the pixel module 170 is lifted under the action of the airflow, and the pixel module 170 is flipped from the left to the right, so that the light-emitting surface of the pixel module 170 is flipped from facing the bottom of the first groove 112 to facing the opening of the first groove 112.

After the main air flow channel 150 and the first main airway 117 are communicated for 5 seconds, the control module 133 controls the second solenoid valve 136 to close and the third solenoid valve 137 to open, so that the first main airway 117 is closed, and the main air flow channel 150 and the second main airway 119 are communicated. The gas of the air pump 140 thus enters the second main airway 119 through the main air flow channel 150. Then the second main airway 119 diverts the gas to the plurality of second airway branches 120. The air flow then blows out from the lower right side of the first groove 112, so that the lower right side of the pixel module 170 is lifted under the action of the air flow, and the pixel module 170 is flipped from facing the bottom of the first groove 112 to facing the opening of the first groove 112.

After the main air flow channel 150 and the second main airway 119 are communicated for 5 seconds, the control module 133 controls the third solenoid valve 137 to close and the fourth solenoid valve 138 to open, so that the second main airway 119 is closed, and the main air flow channel 150 is communicated to the main airway 122 of the third airflow channel 124. The airflow thus passes through the third airflow channel 124 and blows toward the right side of the pixel module 170, so that the pixel module 170 rotates from the right side located in the first groove 112, so that when the left side rotation does not form the alignment between the second magnet 172 and the fourth magnet 114, the pixel module 170 can be rotated on the right side, and so the second magnet 172 and the fourth magnet 114 on the side wall of the first groove 112 can correspond to each other during the rotation of the pixel module 170, thereby forming magnetic attraction and positioning.

That is, in the present application, the control module 133 controls the first solenoid valve 135, the second solenoid valve 136, the third solenoid valve 137, and the fourth solenoid valve 138 to open for a preset time at the same interval according to the detection signal transmitted by the signal processing module 132 by adopting a timing control method, so as to sequentially sweep and blow the pixel module 170 from the left side, the lower left side, the lower right side, and the right side, so that the position of the pixel module 170 is adjusted by rotating and flipping in different directions under the blowing of the airflow, and so the pixel module 170 is magnetically fixed to the first groove 112 at the correct installation position, and the light-emitting surface of the pixel module 170 faces the opening direction of the first groove 112, thereby ensuring the normal display of the display panel 100.

Furthermore, in order to determine whether the pixel module 170 is installed in the correct position of the substrate 110 by detecting the state of the pixel module 170, so that the signal processing module 132 can obtain the detection signal to control the opening or closing of each solenoid valve 134, the present application further improves the detection of the pixel module 170 specifically as follows.

The display panel 100 further includes a plurality of cameras 180. At least two cameras 180 are disposed at diagonal positions of the substrate 110. The cameras 180 are electrically connected to the circuit control layer 160. The cameras 180 are used to detect a display state of the pixel module 170. When the cameras 180 detect that the pixel module 170 is in a first display state, the cameras 180 transmit a detection signal to the signal processing module 132.

In this application, a coil is used to supply power between pixel module 170 and substrate 110. If the light-emitting surface of pixel module 170 faces the inside of first groove 112, the corresponding pixel module 170 should be in a dark state. Therefore, this application obtains the display state of each pixel module 170 installed on the substrate 110 through the cameras 180. When the camera 180 detects that the pixel module 170 is in a first display state, the camera 180 transmits the obtained image information to the signal processing module 132. The first display state may be the display state when the pixel module 170 is in a dark state. The signal processing module 132 receives the detection signal and processes it, and transmits the processed signal to the control module 133. Then the control module 133 controls each solenoid valve 134 to open in sequence, thereby realizing the sequential communication of each air flow channel, so that the pixel module 170 is swept by air flow in sequence from different directions, and so the pixel module 170 is adjusted to the specified position after rotation and flipping.

FIG. 7 is a schematic diagram of a third embodiment of the display panel of the present application. As shown in FIG. 7, the display panel 100 further includes a lifting device 190 and a first cover plate 191. The first cover plate 191 is made of a transparent material. An orthographic projection area of the first cover plate 191 on the substrate 110 is greater than or equal to an orthographic projection area of the plurality of installation regions 111 on the substrate 110. There are at least two lifting devices 190, and the at least two lifting devices 190 are respectively connected to both sides of the substrate 110. The top of each lifting device 190 is connected to the first cover plate 191. The lifting device 190 can drive the first cover plate 191 to rise and fall in a direction perpendicular to the substrate 110. After the pixel modules 170 are installed, the lifting devices 190 drive the first cover plate 191 to cover the multiple pixel modules 170 and abut against the multiple pixel modules 170 to lie in the same plane.

This embodiment is different from the previous embodiment in that the present embodiment installs a lifting device 190 on each of both sides of the substrate 110, and connects the lifting devices 190 to the first cover plate 191, so that the lifting devices 190 can drive the first cover plate 191 to rise and fall in a direction perpendicular to the substrate 110. After the plurality of pixel modules 170 are installed on the substrate 110, the first cover plate 191 is driven by the lifting devices 190 to descend to abut against the plurality of pixel modules 170, so that even if the plurality of pixel modules 170 are uneven in heights after installation due to installation errors, they will be located in the same plane due to the pressing of the first cover plate 191. In this way, the uneven heights problem of the plurality of pixel modules 170 caused by installation errors is overcome, thereby improving the assembly efficiency of the display panel 100 and ensuring the image display effect of the display panel 100.

The lifting device 190 in the present application may be a pneumatic lifting device 190 or an electric lifting device 190. When the lifting device 190 is a pneumatic lifting device 190, two telescopic sleeve structures may be used. In addition, a pressure relief valve may be disposed on the pneumatic lifting device 190, and an air supply channel may be opened in the substrate 110, and the air supply channel may be connected to the air pump 140. A pressure relief rate of the pressure relief valve may be less than a pressure increase rate in the each telescopic sleeve. When the first cover plate 191 needs to be lifted, the air pump 140 is turned on. The gas enters the pneumatic lifting device 190 through the air supply channel, and the two telescopic sleeves are extended by increasing the air pressure, thereby driving the first cover plate 191 to rise to a preset height relative to the substrate 110. When the first cover plate 191 needs to be lowered, it is only required to turn off the air pump 140 to stop the air supply. The gas in the telescopic sleeve thus would be discharged to the external environment through the pressure relief valve, so that the two sleeves are contracted, driving the first cover plate 191 to descend relative to the substrate 110 until it covers the plurality of pixel modules 170.

When the lifting device 190 is an electric lifting device 190, additional motors may be disposed on both sides of the display panel 100 to drive the telescopic sleeve structures to lift. When the first cover plate 191 needs to be lifted, the motors rotate forward to drive the two telescopic sleeves to extend, thereby driving the first cover plate 191 to rise to a preset height relative to the substrate 110. When the first cover plate 191 needs to be lowered, the motors rotate reversely to drive the two sleeves to contract, thereby driving the first cover plate 191 to fall relative to the substrate 110 until it covers the plurality of pixel modules 170.

This application uses the pneumatic lifting device 190 or the electric lifting device 190 as an example for ease of understanding. Other structures that can achieve lifting functions may also be used, and this application does not limit the specific structure of lifting device 190.

In addition, a first screw hole may be pre-opened in the first substrate 110, and a second screw hole may be defined in the top of the lifting device 190 at a position corresponding to the first screw hole. The first substrate 110 is installed on the lifting device 190 by passing a screw through the first screw hole and the second screw hole. Then the first cover plate 191 is driven up or down by the lifting device 190. Furthermore, when the screw is used for fixing, the first cover plate 191 may be installed or removed depending on actual needs. Or, when the first cover plate 191 is damaged, the first cover plate 191 can be replaced, thereby saving costs and facilitating the repair of the display panel 100. Of course, other methods may also be used to install the first cover plate 191 and the lifting device 190 together. For example, the first cover plate 191 may be connected to the top of each of the lifting devices 190 by using a snap-fitting method. This application does not specifically limit the connection method between the first cover plate 191 and the lifting device 190, and only uses the connection method of the first cover plate 191 and the lifting device 190 by screw fixing as an example.

The side of the first cover plate 191 facing the pixel module 170 is a horizontal plane. Therefore, under the pressing of the first cover plate 191, even if the multiple pixel modules 170 are uneven in heights after installation due to installation errors, they will be located in the same plane due to the pressing of the first cover plate 191. This overcomes the unevenness in heights of the multiple pixel modules 170 due to installation errors, thereby improving the assembly efficiency of the display panel 100 and ensuring the image display effect of the display panel 100. When the first cover plate 191 is made of a transparent material, such as a glass material, the first cover plate 191 will not block the light emission of the pixel module 170 when pressing the multiple pixel modules 170, so that the normal display of the display panel 100 will not be affected.

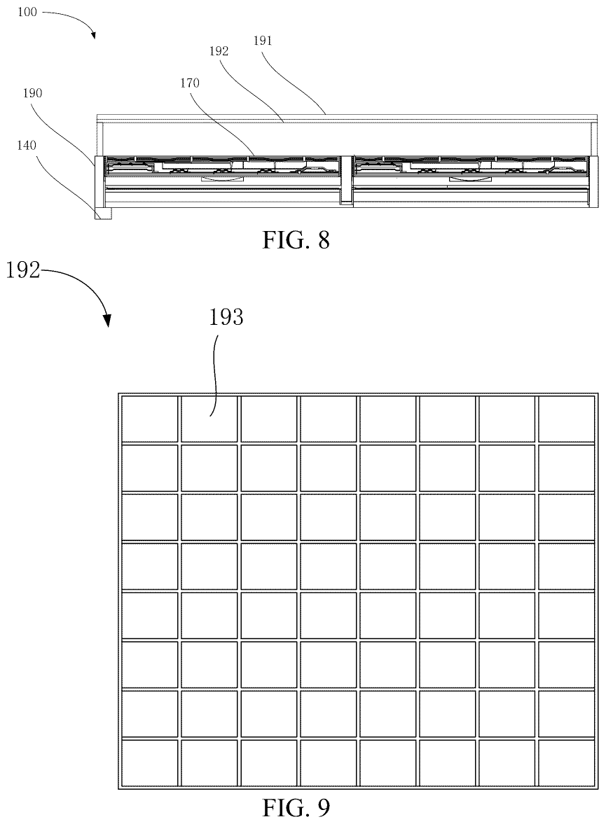

FIG. 8 is a schematic diagram of a fourth embodiment of the display panel of the present application. FIG. 9 is a schematic diagram of a second cover plate in the fourth embodiment of the display panel of the present application. As shown in FIG. 8 and FIG. 9, the display panel 100 further includes a second cover plate 192. An orthographic projection area of the second cover plate 192 on the substrate 110 is equal to an orthographic projection area of the first cover plate 191 on the substrate 110. A through hole 193 is defined at a position corresponding to each installation region 111 on the second cover plate 192. An area of the through hole 193 is larger than an area of the pixel module 170. The second cover plate 192 is located between the first cover plate 191 and the lifting device 190, and is detachably connected to the first cover plate 191 and the lifting devices 190. Before the pixel modules 170 are installed, the lifting devices 190 drive the second cover plate 192 to rise to a preset height.

The present embodiment is different from the previous embodiment in that, in the present embodiment, before installing the plurality of pixel modules 170, the second cover plate 192 may be installed on the lifting device 190. A third screw hole may be pre-opened in the second cover plate 192, and the lifting device 190 may define a second screw hole at a position corresponding to the third screw hole of the second cover plate 192. Then the third screw hole and the second screw hole may be fixed by screws, so that the second cover plate 192 is installed on the lifting device 190. Of course, other methods may also be used to assemble the second cover plate 192 and the lifting device 190 together. For example, the second cover plate 192 may be connected to the top of each lifting device 190 by using a snap connection method. This application does not specifically limit the connection method between the second cover plate 192 and the lifting device 190, and only takes the connection between the second cover plate 192 and the lifting device 190 by means of screw fixing as an example.

Before installing the plurality of pixel modules 170, the second cover plate 192 may be fixed to the tops of the lifting devices 190 by screws. Then, driven by the lifting devices 190, the second cover plate 192 is raised to a preset height relative to the substrate 110, so that the second cover plate 192 can provide a certain space for the installation of the pixel modules 170.

When the plurality of pixel modules 170 are poured from overhead the substrate 110 in order to quickly install the plurality of pixel modules 170, when the plurality of pixel modules 170 fall from over the second cover plate 192, they will pass through through holes 193 of second cover plate 192 and fall onto substrate 110, so that the normal pouring of the plurality of pixel modules 170 on substrate 110 will not be affected. Furthermore, when the plurality of pixel modules 170 bounce after contacting the substrate 110, they will be blocked by the second cover plate 192. Thus, the second cover plate 192 is used to restrict the plurality of pixel modules 170 between the second cover plate 192 and the substrate 110 to prevent the pixel modules 170 from falling outside the substrate 110, thereby effectively improving the installation efficiency of the pixel modules 170.

After the plurality of pixel modules 170 are installed on substrate 110, the first cover plate 191 can be installed on top of the second cover plate 192. The lifting devices 190 drive the second cover plate 192 and the first cover plate 191 to descend at the same time until the entire surface of the first cover plate 191 is pressed onto the pixel modules 170, so that the plurality of pixel modules 170 are lying on the same horizontal plane. This overcomes the unevenness in heights of the multiple pixel modules 170 due to installation errors, thereby improving the assembly efficiency of the display panel 100 and ensuring the image display effect of the display panel 100.

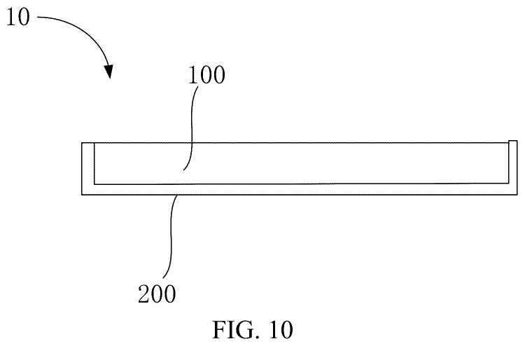

FIG. 10 is a schematic diagram of an embodiment of a display device of the present application. As shown in FIG. 10, embodiments of the present application further disclose a display device 10, including a housing 200. The display device 10 further includes the above-mentioned display panel 100, and the display panel 100 is arranged in the housing 200. The housing 200 is used to protect the display panel 100 from being damaged by external impact, and can also effectively solve the problem of corrosion inside the display panel 100 caused by intrusion of external water vapor.

The display device 10 of the present application mainly includes a display device 10 having an OLED (Organic Light-Emitting Diode) display panel 100, which may be a mobile phone, a computer, a television, etc. The present application does not specifically limit the type of the display device 10. In the present application, the display panel 100 in the display device 10 is mainly composed of a plurality of pixel modules 170 that can emit light independently.

During the assembly process of the display panel 100, when multiple pixel modules 170 are installed one by one on the substrate 110, the installation workload is large, which greatly reduces the assembly efficiency of the display device 10.

Based on the above problems, the present application improves the display panel 100 in the display device 10. Specifically, a first groove 112 is opened in the substrate 110, and a second magnet 172 and a fourth magnet 114 are disposed in the first groove 112. A first magnet 171 and a third magnet 113 are disposed at corresponding positions on the pixel module 170. When installing multiple pixel modules 170, the multiple pixel modules 170 can first be poured on the substrate 110. Since the first magnet 171 of the pixel module 170 and the corresponding third magnet 113 on the substrate 110 have a relatively large magnetic force therebetween, after the pixel module 170 contacts the substrate 110, the pixel module 170 will first be attracted toward the direction of the third magnet 113 through the first magnet 171, so that the pixel module 170 approaches the first groove 112. When approaching the first groove 112, the third magnets 113 on both sides of the pixel module 170 will generate magnetic attraction with the fourth magnets 114 on the groove walls of the first groove 112. Even if the position of the pixel module 170 does not correspond to the position of the first groove 112 at the beginning, the third magnets 113 and the fourth magnets 114 will attract each other to make the pixel module 170 rotate to the position matching the first groove 112 and embed it into the first groove 112. That is, the present application uses the first magnet 171 and the third magnet 113 having a relatively stronger magnetic force therebetween to attract each other to fix the pixel module 170 to the substrate 110 by magnetic attraction, so that the pixel module 170 is not easy to fall off from the substrate 110, and further uses the second magnets 172 and the fourth magnets 114 having a relatively weaker magnetic force to adjust the alignment between the pixel module 170 and the first groove 112, so that the pixel module 170 can be quickly and accurately installed in the first groove 112. In this way, multiple pixel modules 170 can be quickly installed at the specified positions of the substrate 110, improving the assembly efficiency of the display panel 100, thereby improving the assembly efficiency of the display device 10 and saving costs.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A display panel, comprising a substrate and a plurality of pixel modules, wherein the plurality of pixel modules are used for emitting light independently, wherein the substrate is divided into a plurality of installation regions, wherein there is disposed a first groove in each of the plurality of installation regions, and wherein each of the plurality of pixel modules is installed in the respective first groove;
wherein there is disposed a first magnet on a bottom of each of the plurality of pixel modules, wherein there is disposed a second magnet on each of two opposite sides of the pixel module, wherein there is arranged a third magnet at a position of each of the plurality of first grooves corresponding to the respective first magnet, wherein there is arranged a fourth magnet at a position of a groove wall of the first groove corresponding to each second magnet;
wherein a magnetic force between the first magnet and the third magnet is greater than a magnetic force between the second magnet and the fourth magnet;
wherein the first magnet and the third magnet have opposite magnetic polarities, and wherein the second magnet and the fourth magnet have opposite magnetic polarities.

2. The display panel as recited in claim 1, wherein each of the plurality of pixel modules has only one pixel unit, and wherein each pixel unit comprises a red sub-pixel, a green sub-pixel, and a blue sub-pixel.

3. The display panel as recited in claim 2, wherein there is disposed a pixel driving circuit in each of the plurality of pixel modules, wherein the pixel driving circuit is configured to drive the pixel module to emit light and display; wherein the pixel driving circuit comprises a communication unit and a control unit, wherein the communication unit is configured to receive a data signal, wherein the communication unit is configured to transmit the data signal to the control unit, and wherein the control unit is configured to control the pixel module to emit light and display.

4. The display panel as recited in claim 3, wherein each of the plurality of pixel modules comprises a base, and a light-emitting layer and an encapsulation layer that are arranged on the base in sequence, wherein there is arranged a power receiving terminal on a side of the base facing away from the light-emitting layer, wherein there is arranged a power supply terminal in the substrate corresponding to the power receiving terminal; wherein the power supply terminal is configured to provide an electrical signal to the power receiving terminal to power up the pixel driving circuit.

5. The display panel as recited in claim 4, wherein the power receiving terminal comprises a first coil, wherein the power supply terminal comprises a second coil, wherein there is arranged a plurality of the power supply terminals in one-to-one correspondence with the power receiving terminals on the plurality of the pixel modules.

6. The display panel as recited in claim 5, wherein the first coil and the second coil are operative to transmit signals wirelessly to realize power supply to the respective pixel module.

7. The display panel as recited in claim 6, wherein the communication unit comprises a wireless receiving module, which is used to receive an external data signal, and generate a data control signal based on the external data signal and transmit the data control signal to the respective control unit.

8. The display panel as recited in claim 4, wherein there is disposed a bare metal gasket at a bottom of each of the plurality of pixel modules and another bare metal gasket in the respective installation region in which the pixel module is installed, wherein when the respective pixel module is installed in the installation region, the respective power receiving terminal is operative to contact the respective power supply terminal to achieve an electrical connection.

9. The display panel as recited in claim 1, wherein there is disposed a first airflow channel in the substrate, wherein the first airflow channel is disposed at a bottom of each of the plurality of first grooves and is communicated to the bottom of the first groove; wherein there are disposed a second airflow channel and a third airflow channel in two opposite side walls of each of the plurality of first grooves, respectively; wherein the second airflow channel and the third airflow channel are communicated to two sides of the side walls of the respective first groove facing towards the respective pixel module, respectively;
wherein there is disposed a control assembly in the substrate, wherein the control assembly is separately connected to the first airflow channel, the second airflow channel, and the third airflow channel,
wherein the display panel further comprises an air pump arranged on a side of the substrate facing away from the plurality of pixel modules; wherein there is further arranged a main air flow channel on the substrate, and the main air flow channel is connected between the air pump and the control assembly;
wherein in response to the air pump being turned on, the control assembly is configured to control the second airflow channel, the first airflow channel, and the third airflow channel to be communicated to the main air flow channel in turn for a preset period of time within equal time intervals.

10. The display panel as recited in claim 9, wherein the control assembly is configured to connect the first airflow channel, the second airflow channel, and the third airflow channel to the air pump through the main air flow channel by in a coded timing manner.

11. The display panel as recited in claim 9, wherein there are disposed a plurality of fourth magnets, and wherein the plurality of fourth magnets are arranged at intervals along a side wall of the first groove in a direction perpendicular to the substrate;
wherein the second airflow channel and the third airflow channel each comprise a main airway and a plurality of airway branches, wherein the main airway extends from the side wall of the first groove in the direction perpendicular to the substrate and is connected to the control assembly;
wherein each of the plurality of airway branches is disposed in a respective gap between every two adjacent fourth magnets, and wherein one end of each of the plurality of airway branches is communicated to a side of the side wall of the first groove facing towards the respective pixel module, and wherein another end of the airway branch is communicated to a side of the main airway facing towards the pixel module.

12. The display panel as recited in claim 11, wherein the first magnet is located in a middle of the respective pixel module, wherein the first groove comprises a second groove corresponding to a position of the first magnet, wherein the second groove has a shape that matches a shape of the first magnet, and wherein the first magnet is embedded in the second groove;
wherein the first airflow channel comprises a first main airway, a second main airway, a plurality of first airway branches, and a plurality of second airway branches, wherein one end of the first main airway is connected to the control assembly, and another end of the first main airway extends along a length direction of the substrate;
wherein one end of the second main airway is connected to the control assembly, and another end of the second main airway extends along the length direction of the substrate; and wherein the first main airway and the second main airway are arranged at intervals,
wherein the plurality of first airway branches are arranged at intervals, and wherein one end of each of the plurality of first airway branches is communicated to a bottom of the first groove, and wherein another end of the first airway branch is communicated to a side of the first main airway facing towards the first groove;
wherein the plurality of second airway branches are arranged at intervals, and wherein one end of each of the plurality of second airway branches is communicated to a bottom of the first groove, and wherein another end of the second airway branch is connected to a side of the second main airway facing towards the first groove;
wherein the plurality of first airway branches and the plurality of second airway branches are respectively disposed on two sides of the second groove;
wherein in response to the air pump being turned on, the control assembly is configured to control the first main airway and the second main airway to be communicated to the main air flow channel in turn for a preset period of time within equal time intervals.

13. The display panel as recited in claim 12, wherein the control assembly is configured to communicate the main air flow channel with the first main airway or the second main airway for a continuous period of 5 seconds.

14. The display panel as recited in claim 13, wherein the substrate comprises a circuit control layer, the control assembly comprises a circuit board, wherein the circuit board is electrically connected to the circuit control layer, and wherein the circuit control layer is configured to provide an electrical signal to the circuit board;
wherein the circuit board comprises a signal processing module, a control module, and a plurality of solenoid valves; wherein the signal processing module is electrically connected to the control module, wherein the control module is electrically connected to the plurality of solenoid valves; wherein the signal processing module is used to receive a detection signal;
wherein the solenoid valve comprises a first solenoid valve, a second solenoid valve, a third solenoid valve, and a fourth solenoid valve; wherein one end of the first solenoid valve, one end of the second solenoid valve, one end of the third solenoid valve, and one end of the fourth solenoid valve are each connected to the main air flow channel, wherein another end of the first solenoid valve is connected to the main airway of the second airflow channel, wherein the first solenoid valve is configured to control the main airway of the second airflow channel to be communicated to or cut off from the main air flow channel; wherein another end of the second solenoid valve is connected to the first main airway, and the second solenoid valve is configured to control the first main airway to be communicated to or cut off from the main air flow channel; wherein another end of the third solenoid valve is connected to the second main airway, and the third solenoid valve is configured to control the second main airway to be communicated to or cut off from the main air flow channel; wherein another end of the fourth solenoid valve is connected to the main airway of the third airflow channel, and the fourth solenoid valve is configured to control the main airway of the third airflow channel to be communicated to or cut off from the main air flow channel; wherein in response to the signal processing module receiving a detection signal, the signal processing module is configured to transmit the detection signal to the control module, and the control module is configured to control the first solenoid valve, the second solenoid valve, the third solenoid valve, and the fourth solenoid valve to be opened for a preset period of time within equal time intervals.

15. The display panel as recited in claim 14, wherein the display panel further comprises a plurality of cameras, wherein at least two of the plurality of cameras are arranged at diagonals of the substrate, wherein the at least two cameras are electrically connected to the circuit control layer, wherein the at least two cameras are used to detect a display state of the pixel module, wherein in response to the at least two cameras detecting that the pixel module is in a first display state, the at least two cameras are configured to transmit a detection signal to the signal processing module.

16. The display panel as recited in claim 1, wherein the display panel further comprises at least two lifting devices and a first cover plate, the first cover plate being made of a transparent material; wherein an orthographic projection area of the first cover plate on the substrate is greater than or equal to an orthographic projection area of the plurality of the installation regions on the substrate;
wherein the at least two lifting devices are connected to two sides of the substrate, respectively, wherein a top of each of the at least two lifting devices is connected to the first cover plate, wherein the at least two lifting devices are operative to drive the first cover plate to rise and fall in a direction perpendicular to the substrate;
wherein after the plurality of pixel modules are installed, the at least two lifting devices are configured to drive the first cover plate to cover the plurality of pixel modules and abut against the plurality of pixel modules to lie in a same plane so that the respective tops of the plurality of pixel modules are flush with each other.

17. The display panel as recited in claim 16, wherein the at least two lifting devices comprise a pneumatic lifting device or an electric lifting device.

18. The display panel as recited in claim 16, further comprising a second cover plate, wherein an orthographic projection area of the second cover plate on the substrate is equal to an orthographic projection area of the first cover plate on the substrate; wherein the second cover plate defines a through hole corresponding to each of the plurality of installation regions, wherein an area of the through hole is greater than an area of each of the plurality of pixel modules;
wherein the second cover plate is disposed between the first cover plate and the at least two lifting devices, and is detachably connected to the first cover plate and the at least two lifting devices;
wherein before the plurality of pixel modules are installed, the at least two lifting devices are configured to drive the second cover plate to rise to a preset height.

19. The display panel as recited in claim 1, wherein there is arranged a pixel driving circuit in each of the plurality of pixel modules, wherein the pixel driving circuit is configured to drive the pixel module to emit light and display; wherein the pixel driving circuit comprises a communication unit and a control unit, wherein the communication unit is used to receive a data signal, wherein the communication unit is configured to transmit the data signal to the control unit, and wherein the control unit is configured to control the pixel module to emit light and display;
wherein the pixel module comprises a base, and a light-emitting layer and an encapsulation layer that are sequentially arranged on the base, wherein there is arranged a power receiving terminal on a side of the base facing away from the light-emitting layer, wherein there is arranged a power supply terminal in the substrate corresponding to the power receiving terminal; wherein the power supply terminal is configured to provide an electrical signal to the power receiving terminal to power up the pixel driving circuit.

20. A display device comprising a housing and a display panel arranged in the housing; wherein the display panel comprises a substrate and a plurality of pixel modules, wherein the plurality of pixel modules are used for emitting light independently, wherein the substrate is divided into a plurality of installation regions, wherein there is disposed a first groove in each of the plurality of installation regions, and wherein each of the plurality of pixel modules is installed in the respective installation region;
wherein there is disposed a first magnet on a bottom of each of the plurality of pixel modules, wherein there is disposed a second magnet on each of two opposite sides of the pixel module, wherein there is arranged a third magnet at a position of each of the plurality of first grooves corresponding to the respective first magnet, wherein there is arranged a fourth magnet at a position of a groove wall of the first groove corresponding to each second magnet;
wherein a magnetic force between the first magnet and the third magnet is greater than a magnetic force between the second magnet and the fourth magnet;
wherein the first magnet and the third magnet have opposite magnetic polarities, and wherein the second magnet and the fourth magnet have opposite magnetic polarities.
